(19) United States
(12) Patent Application Publication
(10) Pub. No.: US 2025/0185221 A1
(43) Pub. Date: Jun. 5, 2025

(54) POWER CONVERSION APPARATUS

(71) Applicant: LS ELECTRIC CO., LTD., Anyang-si, Gyeonggi-do (KR)

(72) Inventor: Bo Sun SONG, Anyang-si, Gyeonggi-do (KR)

(21) Appl. No.: 18/726,581

(22) PCT Filed: Jan. 2, 2023
(86) PCT No.: PCT/KR2023/000038

§ 371 Date: Jul. 3, 2024

(30) Foreign Application Priority Data
Jan. 6, 2022 (KR) 10-2022-0002119

(51) Int. Cl. H05K 7/20; H02M 3/00

(52) U.S. Cl. CPC H05K 7/209; H02M 3/003

(57) ABSTRACT

A power conversion apparatus is disclosed. The power conversion apparatus according to one aspect of the present disclosure may include: a housing including an upper part, a lower part disposed in parallel with the upper part, a first side part connecting the upper part with the lower part, and a second side part disposed in parallel with the first side part; a plurality of transistors disposed adjacent to the first side part inside the housing; a heat sink disposed on one side of the plurality of transistors and providing a passage through which air introduced from the outside moves; and a plurality of capacitors disposed in front of the heat sink, wherein the plurality of capacitors may be disposed to be spaced apart from each other so that air introduced from the outside of the housing moves to the heat sink.

### CROSS-REFERENCE TO RELATED APPLICATIONS

This application is the National Stage filing under 35 U.S.C. 371 of International Application No. PCT/KR2023/000038, filed on Jan. 2, 2023, which claims the benefit of earlier filing date and right of priority to Korean Application No. 10-2022-0002119, filed on Jan. 6, 2022, the contents of which are all hereby incorporated by reference herein in their entirety.

### FIELD

The present disclosure relates to a power conversion apparatus, and more particularly, to a power conversion apparatus having improved heat dissipation efficiency to prevent damage by heat.

### BACKGROUND

In general, an uninterruptible power supply (UPS) is a device that prevents power abnormalities due to voltage fluctuations, frequency fluctuations, instantaneous power outages, transient voltages, etc. and supplies stable power when using general power or spare power. Such an uninterruptible power supply is connected between a battery and a mechanical or electronic device installed in a factory to secure the stable operation of the mechanical or electronic device. In addition, recently, as stability of operation of electronic devices used in finance, broadcasting, etc. is required, the introduction of the uninterruptible power supply is spreading.

The uninterruptible power supply is equipped with a power conversion apparatus that converts direct current (DC) power into power suitable for application to other loads. One of the power conversion apparatuses is a DC-to-DC converter that converts DC power into another DC power.

This power conversion apparatus is provided with a plurality of transistors and a plurality of capacitors. A problem arises in that heat generated from the plurality of capacitors damages the plurality of transistors. When the plurality of transistors are disposed to be excessively far away from each other in order to prevent the plurality of transistors from being damaged the heat, there is a problem that the overall resistance of the power conversion apparatus increases.

The damage caused by the heat of the plurality of capacitors and the increase in the overall resistance of the power conversion apparatus are in a trade-off relationship.

### SUMMARY

The present disclosure is to solve the above problems, and an object of the present disclosure is to provide a power conversion apparatus having improved heat dissipation efficiency to prevent damage by heat.

Another object of the present disclosure is to provide a power conversion apparatus in which resistance of the power conversion apparatus is prevented from increasing by not disposing a plurality of transistors to be excessively spaced apart.

Still another object of the present disclosure is to provide a power conversion apparatus with improved convenience when installing or replacing the power conversion apparatus.

The objects of the present disclosure are not limited to the above-mentioned objects, and other objects not mentioned will be clearly understood by those skilled in the art from the following description.

The power conversion apparatus according to one aspect of the present disclosure may include: a housing including an upper part, a lower part disposed in parallel with the upper part, a first side part connecting the upper part with the lower part, and a second side part disposed in parallel with the first side part; a plurality of transistors disposed adjacent to the first side part inside the housing; a heat sink disposed on one side of the plurality of transistors and providing a passage through which air introduced from the outside moves; and a plurality of capacitors disposed in front of the heat sink, wherein the plurality of capacitors may be disposed to be spaced apart from each other so that air introduced from the outside of the housing moves to the heat sink.

In this case, the plurality of transistors may be disposed in parallel with the upper part, and may be disposed to be alternately spaced apart from each other by a first interval and a second interval greater than the first interval.

The plurality of capacitors may include: a plurality of first capacitors arranged in a row parallel with the first interval; and a plurality of second capacitors arranged in two rows parallel with the second interval.

The plurality of second capacitors may be disposed to be spaced apart from each other at a third interval smaller than the first interval, and the plurality of first capacitors and the plurality of second capacitors may be disposed to be spaced apart from each other at a fourth interval greater than the third interval.

In this case, some capacitors disposed at the front among the plurality of second capacitors may be disposed to be spaced apart from each other at a fifth interval greater than the fourth interval.

The power conversion apparatus may further include an air blocking unit having a plate shape and formed to have a plurality of passage holes through which the plurality of capacitors pass, wherein the air blocking unit can block air introduced into the plurality of capacitors from being moved to the plurality of transistors.

The power conversion apparatus may further include an air guide extending from the second side part and formed to be inclined, wherein the air guide can guide air introduced from the outside to be supplied to one side of the heat sink.

The power conversion apparatus may further include: a substrate electrically connected to the transistor and the plurality of capacitors; a bus bar having one end electrically connected to the substrate and the other end protruding to the rear of the housing; and a coupling part coupled to the other end of the bus bar and detachably coupled to a connector of an uninterruptible power supply.

According to the configuration described above, in the power conversion apparatus according to an embodiment of the present disclosure, the plurality of transistors and the plurality of capacitors are disposed so as not to be excessively spaced apart from each other, so that the resistance of the power conversion apparatus is not increased, and the plurality of capacitors are disposed to be spaced apart from each other, so that air introduced from the outside of the housing moves smoothly to the heat sink, thereby preventing the transistor from being damaged by heat.

In addition, since the coupling part is detachably coupled to the connector of the uninterruptible power supply, the convenience of installing or replacing the power conversion apparatus is improved.

### BRIEF DESCRIPTION OF THE DRAWINGS

FIG. 1 is a perspective view showing the inside of an uninterruptible power supply according to an embodiment of the present disclosure.

FIG. 2 is a perspective view showing an external appearance of a power conversion apparatus according to an embodiment of the present disclosure.

FIG. 3 is a perspective view of an external appearance of a power conversion apparatus according to an embodiment of the present disclosure as viewed from another side.

FIG. 4 is an exploded perspective view illustrating a state in which a plurality of transistors, a heat sink, a plurality of capacitors, and a substrate of a power conversion apparatus according to an embodiment of the present disclosure are separated.

FIG. 5 is a side view illustrating the inside of a power conversion apparatus according to an embodiment of the present disclosure.

FIG. 6 is a rear view illustrating the inside of a power conversion apparatus according to an embodiment of the present disclosure.

FIG. 7 is a diagram showing a state before a power conversion apparatus according to an embodiment of the present disclosure is connected to an uninterruptible power supply.

FIG. 8 is a diagram illustrating a state in which a power conversion apparatus according to an embodiment of the present disclosure is connected to an uninterruptible power supply.

| | |
|---|---|
| 100: POWER CONVERSION APPARATUS | 110: housing |
| 111: upper part | 112: lower part |
| 113: first side part | 114: second side |
| 120: transistor | 130: heat sink |
| 140: a plurality of capacitors | |

### DETAILED DESCRIPTION

Hereinafter, with reference to the accompanying drawings, embodiments of the present disclosure will be described in detail so as to be easily implemented by one of ordinary skill in the art to which the present disclosure pertains. The present disclosure may be embodied in a variety of forms and is not limited to the embodiments described herein. In order to clearly describe the present disclosure, parts irrelevant to the description are omitted from the drawings; and throughout the specification, same or similar components are referred to as like reference numerals.

The words and terms used in the specification and claims of the present application are not to be construed as being limited to their ordinary or dictionary meanings, but should be interpreted as meanings and concepts consistent with the technical spirit of the present disclosure, based on the principle that the inventor may define terms and concepts to best describe his disclosure.

Therefore, the embodiments described in the specification and the configuration shown in the drawings correspond to preferred embodiments of the present disclosure, and do not represent the entire technical ideas of the present disclosure, so the configurations may have various equivalents and variations to replace them at the time of filing the present disclosure.

In the specification, terms such as “comprise” or “have” are intended to explain that a feature, number, step, operation, component, part or combination thereof described in the specification is present, but should not be construed to preclude the possibility of the presence or addition of one or more other features, numbers, steps, operations, components, parts or combinations thereof.

When a component is said to be “before”, “after”, “above” or “below” another component, it includes a case in which the component is placed “before”, “after”, “above” or “below” another component so as to be in direct contact with each other, as well as a case where any additional component is disposed between the two components, unless there are special circumstances. In addition, when a component is said to be “connected” to another component, it includes cases where they are not only directly connected to each other but also indirectly connected to each other, unless there are special circumstances.

Hereinafter, a power conversion apparatus according to an embodiment of the present disclosure will be described with reference to the drawings.

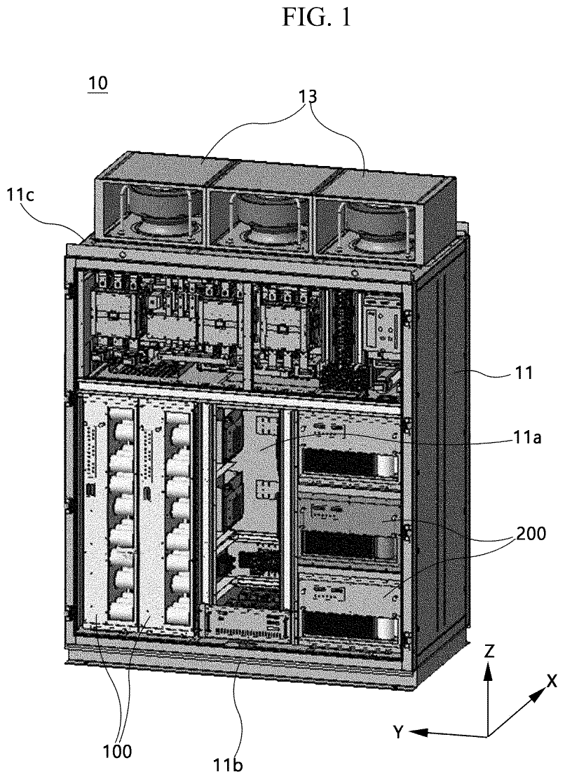

FIG. 1 is a perspective view showing the inside of an uninterruptible power supply according to an embodiment of the present disclosure.

Referring to FIG. 1, the uninterruptible power supply 10 according to an embodiment of the present disclosure includes a case 11 and power conversion apparatuses 100 and 200.

The case 11 is provided with an accommodation space 11a in which the power conversion apparatuses 100 and 200 and power devices are accommodated. The case 11 is made of a metal material. However, the case 11 is not limited to being made of a metal material, and may be made of various materials such as plastic having rigidity.

The power conversion apparatuses 100 and 200 include a first power conversion apparatus 100 and a second power conversion apparatus 200.

The first power conversion apparatus 100 is disposed in a direction perpendicular to the lower surface 11b of the case 11. The first power conversion apparatus 100 is an AC-DC converter that converts alternating current (AC) power into direct current (DC). However, the first power conversion apparatus 100 is not limited to the AC-DC converter, and may be an DC-DC converter that converts direct current (DC) power to DC power or a DC-AC converter that converts DC power to AC power. In this case, the first power conversion apparatus 100 is configured in plural, and the plurality of first power conversion apparatuses 100 are disposed in parallel with each other. Accordingly, the plurality of first power conversion apparatuses 100 are prevented from applying load to each other.

The second power conversion apparatus 200 is disposed in parallel with the lower surface 11b of the case 11. The second power conversion apparatus 200 is a direct current-to-direct current converter that converts direct current (DC) power into another direct current (DC) power. However, the second power conversion apparatus 200 is not limited to the DC-DC converter, and may be an AC-DC converter that converts alternating current (AC) power to DC power or a DC-AC converter that converts DC power to AC power. In this case, the second power conversion apparatus 200 is configured in plural, and the plurality of second power conversion apparatuses 200 are disposed to be stacked on each other. The second power conversion apparatus 200 will be described in detail later with reference to the drawings.

In addition, a fan 13 for discharging air from the accommodation space 11a of the case 11 to the outside is provided on the upper surface 11c of the case 11. The fan 13 rotates to suck air from the accommodation space 11a, and the air in the accommodation space 11a is discharged to the outside through the fan 13. Accordingly, since heat generated by the power conversion apparatuses 100 and 200 and the power device is discharged to the outside along the flow of air in the accommodation space 11a, the power conversion apparatuses 100 and 200 are prevented from being damaged by heat.

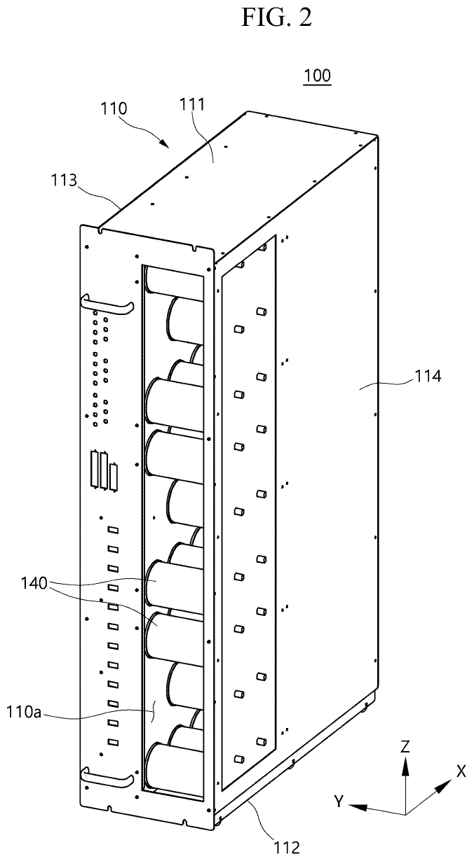

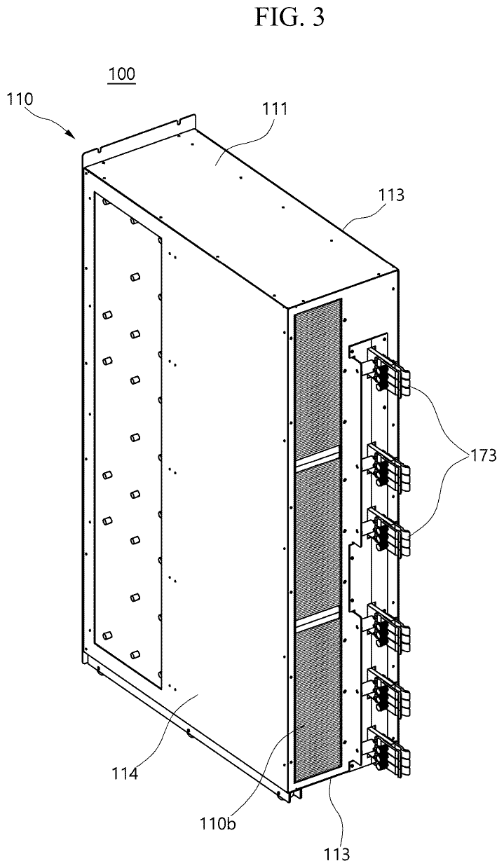

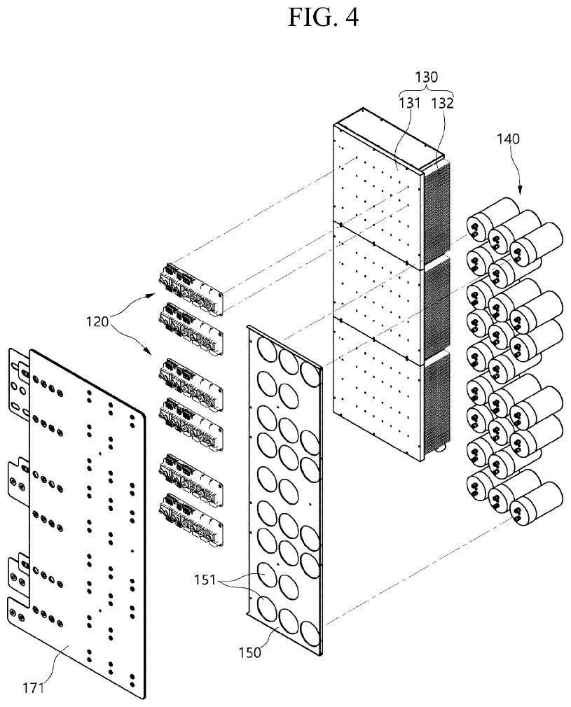

FIG. 2 is a perspective view showing an external appearance of a power conversion apparatus according to an embodiment of the present disclosure, FIG. 3 is a perspective view of an external appearance of a power conversion apparatus according to an embodiment of the present disclosure as viewed from another side, and FIG. 4 is an exploded perspective view illustrating a state in which a plurality of transistors, a heat sink, a plurality of capacitors, and a substrate of a power conversion apparatus according to an embodiment of the present disclosure are separated.

Referring to FIGS. 2 to 4, the power conversion apparatus 100 according to an embodiment of the present disclosure includes a housing 110, a plurality of transistors 120, a heat sink 130, and a plurality of capacitors 140.

The housing 110 has an approximately hexahedral shape. Further, the housing 110 is made of a metal material. However, the housing 110 is not limited to being made of a metal material, and may be made of various materials having rigidity. The housing 110 includes an upper part 111, a lower part 112, a first side part 113, and a second side part 114.

The upper part 111, the lower part 112, the first side part 113 and the second side part 114 are formed in a plate shape. The lower part 112 is disposed in parallel with the upper part 111. The first side part 113 connects the upper part 111 and the lower part 112. The second side part 114 is disposed in parallel with the first side part 113 and connects the upper part 111 and the lower part 112. In this case, the housing 110 is formed to have an air inlet 110a that opens forward, that is, in the x-axis direction. In addition, air outside the housing 110 is introduced into the housing 110 through the air inlet 110a. In addition, the housing 110 is formed to have an air outlet 110b formed at a rear side opposite to the air inlet 110a. In addition, as the heat generated inside the housing 110 is discharged through the air outlet 110b, overheating of the inside of the housing 110 is prevented.

The plurality of transistors 120 are disposed adjacent to the first side part 113 inside the housing 110. In this case, the plurality of transistors 120 are disposed in parallel with the upper part 111 along the X direction. The plurality of transistors 120 are insulated gate bipolar transistors (IGBTs), which are semiconductor devices capable of high-speed switching of high power. However, the plurality of transistors 120 are not limited to the insulated gate bipolar transistors, and may be various switching devices capable of switching power. Since the plurality of transistors 120 are semiconductor devices, the switching function may be deteriorated or damaged by heat generated from the plurality of capacitors 140. Accordingly, the plurality of transistors 120 are disposed in a region of the housing 110 where heat generated from the plurality of capacitors 140 is not excessively transferred, and thus, a function of the plurality of transistors 120 is prevented from being deteriorated or damaged.

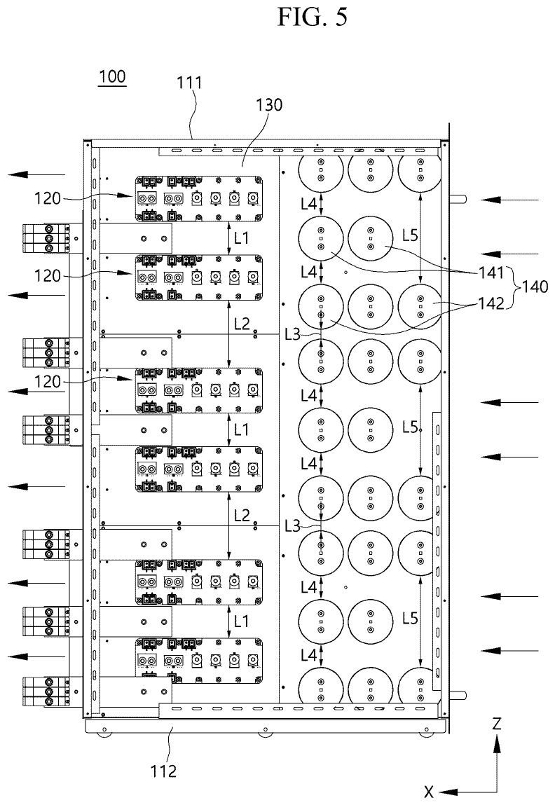

The heat sink 130 is disposed on one side of the transistors 120 inside the housing 110. As shown in FIG. 5, the heat sink 130 provides a passage through which air introduced from the outside of the housing 110 moves. The heat sink 130 is made of copper or aluminum. However, the material of the heat sink 130 is not limited to copper or aluminum, and may be made of various materials having thermal conductivity such as silver. The heat sink 130 receives heat generated from the plurality of transistors 120 and exchanges heat with air to dissipate heat from the plurality of transistors 120. Accordingly, the heat sink 130 prevents the plurality of transistors 120 from being damaged by heat.

The heat sink 130 includes a heat dissipation plate 131 supporting the plurality of transistors 120 and a plurality of heat dissipation fins 132 extending in a vertical direction from the heat dissipation plate 131. The heat dissipation plate 131 is in contact with the transistor 120 to receive heat generated from the transistor 120. The plurality of heat dissipation fins 132 are disposed in parallel with the upper part 111. In this case, a passage through which air introduced from the outside of the housing 110 moves is formed between the plurality of heat dissipation fins 132. In addition, the heat of the heat dissipation plate 131 is transferred to the plurality of heat dissipation fins 132, and the heat of the plurality of heat dissipation fins 132 is heat-exchanged with air. That is, the heat of the plurality of heat dissipation fins 132 is transferred to the air in the passage and thus, the temperature of the air in the passage is increased. In addition, the air with an increased temperature is discharged to the outside of the housing 110 through the air outlet 110b.

The plurality of transistors 120 are disposed in parallel with the plurality of heat dissipation fins 132. Accordingly, the heat of the plurality of transistors 120 is uniformly transferred to each of the plurality of heat dissipation fins 132 through the heat dissipation plate 131, thereby preventing the heat dissipation performance from deteriorating due to the concentration of the heat of the heat dissipation plate 131 on a portion of the plurality of heat dissipation fins 132.

The plurality of capacitors 140 are disposed in front of the heat sink 130 inside the housing 110. The plurality of capacitors 140 are disposed in parallel with each other along the Y direction. In addition, air outside the housing 110 is introduced into the plurality of capacitors 140 through the air inlet 110a of the housing 110. In this case, the plurality of capacitors 140 are disposed to be spaced apart from each other so that the air moves to the heat sink 130. Accordingly, air outside the housing 110 is smoothly moved to the heat sink 130 through between the plurality of capacitors 140.

In addition, as shown in FIG. 4, the power conversion apparatus 100 according to an embodiment of the present disclosure further includes an air blocking unit 150 disposed between the first side part 113 and the second side part 114.

The air blocking unit 150 is formed in a plate shape. In addition, a plurality of passage holes 151 through which some of the plurality of capacitors 140 pass are formed in the air blocking unit 150. Accordingly, the air blocking unit 150 blocks air introduced into the plurality of capacitors 140 from moving to the plurality of transistors 120.

In addition, the power conversion apparatus 100 according to an embodiment of the present disclosure further includes a substrate 171, a bus bar 172, and a coupling part 173.

The substrate 171 is electrically connected to the plurality of transistors 120. In addition, the substrate 171 is electrically connected to the plurality of capacitors 140 partially protruding from the air blocking unit 150 through the plurality of passage holes 151. The bus bar 172 is electrically connected to the substrate 171 and the power device of the uninterruptible power supply 10 (see FIG. 1). One end of the bus bar 172 is electrically connected to the substrate 171, and the other end of the bus bar 172 protrudes toward the rear of the housing 110 through the second opening 100b. The coupling part 173 is coupled to the other end of the bus bar 172. The coupling part 173 is detachably coupled to a connector electrically connected to the power device of the uninterruptible power supply 10 (see FIG. 1). In this way, the plurality of transistors 120 and the plurality of capacitors 140 are electrically connected to the power device of the uninterruptible power supply 10 (see FIG. 1) through the substrate 171, the bus bar 172, and the coupling part 173.

FIG. 5 is a side view illustrating the inside of a power conversion apparatus according to an embodiment of the present disclosure.

Referring to FIG. 5, the plurality of transistors 120 are disposed to be alternately spaced apart from each other by a first interval (L1) and a second interval (L2) greater than the first interval (L1). That is, the plurality of transistors 120 include a pair of transistors 120 spaced apart by the first interval (L1), and the pairs of transistors 120 are disposed to be spaced apart from each other by the second interval (L2).

In addition, the plurality of capacitors 140 include: a plurality of first capacitors 141 arranged in a row parallel with the first interval (L1), and a plurality of second capacitors 142 arranged in two rows parallel with the second interval.

The plurality of first capacitors 141 and the plurality of second capacitors 142 are alternately disposed. In this case, the plurality of second capacitors 142 are disposed to be spaced apart from each other at a third interval (L3) smaller than the first interval (L1). As the plurality of second capacitors 142 are disposed in parallel with the second interval (L2) where the plurality of transistors 120 are not disposed, a space in which the plurality of second capacitors 142 are disposed is reduced, thereby preventing the size of the power conversion apparatus 100 from being increased.

In addition, the plurality of first capacitors 141 and the plurality of second capacitors 142 are disposed to be spaced apart from each other at a fourth interval (L4) greater than the third interval (L3). Accordingly, even though the plurality of transistors 120 are disposed in parallel with the fourth interval (L4), as the plurality of first capacitors 141 and the plurality of second capacitors 142 are disposed to be spaced apart from each other at the fourth interval (L4), the flow of air moving toward the heat sink 130 for heat dissipation of the plurality of transistors 120 is prevented from being reduced, thereby ensuring the heat dissipation performance of the heat sink 130.

In addition, some capacitors disposed toward the front of the housing 110 among the plurality of second capacitors may be disposed to be spaced apart from each other at a fifth interval (L5) greater than the fourth interval (L4). Even though the plurality of transistors 120 are disposed in parallel with the fifth interval (L5), as some capacitors disposed toward the front of the housing 110 among the plurality of second capacitors 142 are disposed to be spaced apart from each other at the fifth interval (L5), the flow of air moving toward the heat sink 130 for heat dissipation of the pair of transistors 120 is prevented from being reduced, thereby ensuring the heat dissipation performance of the heat sink 130.

In this way, the plurality of capacitors 140 are disposed so that the space for placing the plurality of capacitors 140 does not increase excessively, thereby reducing the overall size of the power conversion apparatus 100. Further, the plurality of capacitors 140 are disposed so that the air introduced into the plurality of capacitors 140 is smoothly moved to the heat sink 130 for dissipating heat from the transistor 120 and then discharged to the rear of the heat sink 130, thereby improving the heat generation performance of the power conversion apparatus 100.

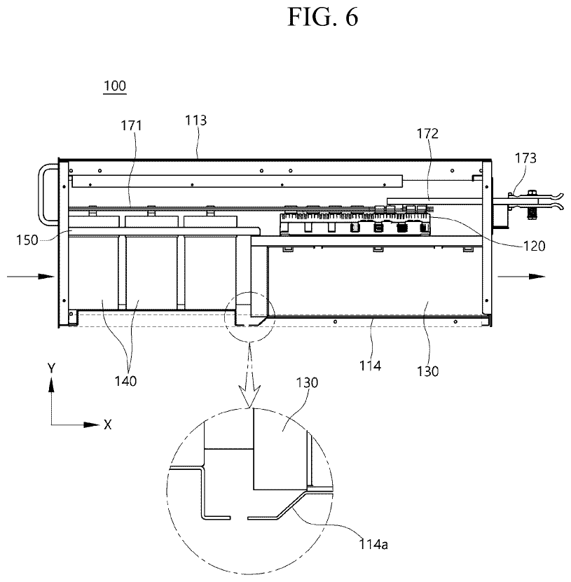

FIG. 6 is a rear view illustrating the inside of a power conversion apparatus according to an embodiment of the present disclosure.

Referring to FIG. 6, the power conversion apparatus 100 according to an embodiment of the present disclosure further includes an air guide 114a extending from the second side part 114.

The air guide 114a is formed to be inclined from the second side part 114. When viewed in FIG. 6, the air guide 114a guides the air introduced from the outside of the housing 110 to be supplied below one side of the heat sink 130. Here, it is noted that the expression “below one side of the heat sink 130” is defined for convenience of description.

Accordingly, even if a vortex of air is generated at one side of the heat sink 130, the air is guided to be supplied below the heat sink 130 by the air guide 115a, so that the air is smoothly supplied to the heat sink 130.

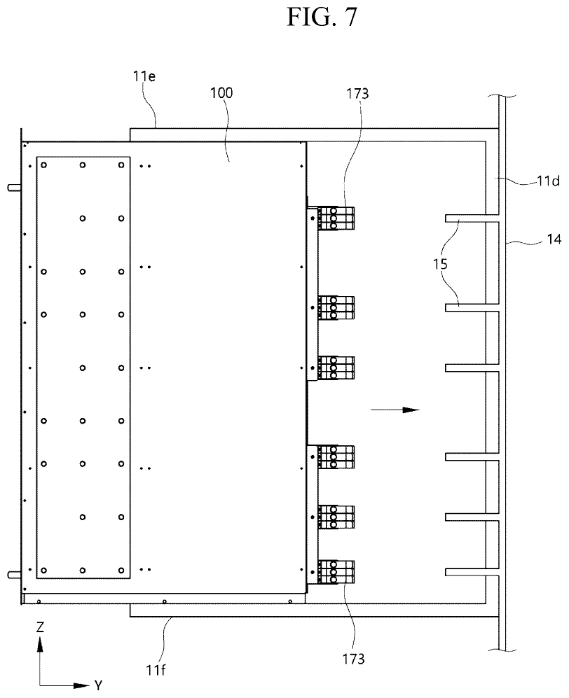

FIG. 7 is a diagram showing a state before a power conversion apparatus according to an embodiment of the present disclosure is connected to an uninterruptible power supply.

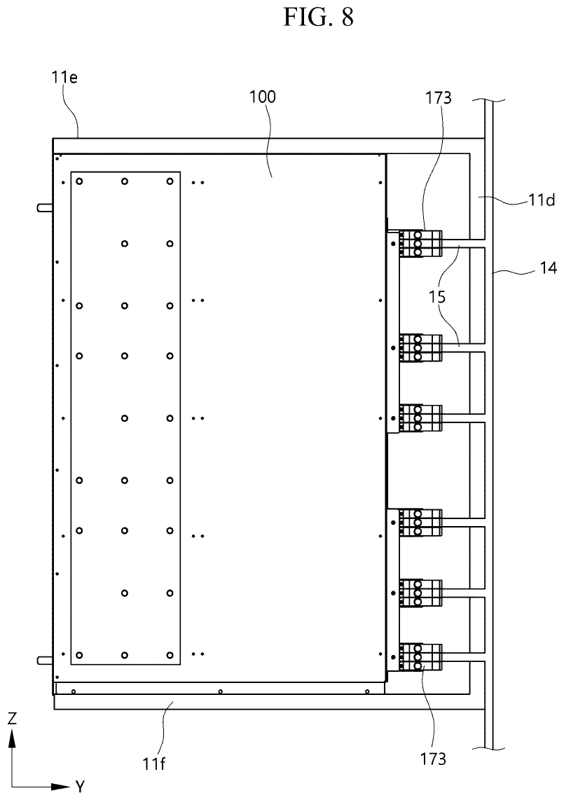

FIG. 8 is a diagram illustrating a state in which a power conversion apparatus according to an embodiment of the present disclosure is connected to an uninterruptible power supply.

A method of connecting the power conversion apparatus 100 according to an embodiment of the present disclosure to the uninterruptible power supply 10 will be described with reference to FIGS. 1, 7 and 8.

The power conversion apparatus 100 is inserted into the case 11. The uninterruptible power supply 10 is provided with a connection part 14 connected to the power device of the power conversion apparatus 100. The connection part 14 is vertically disposed along the inner surface of the case 11. In addition, the connection part 14 includes a connector 15 protruding toward the front of the case 11. The coupling part 173 is detachably coupled to the connector 15. Specifically, the coupling part 173 is formed such that the connector 15 is inserted into the coupling part 173. That is, the connector 15 is inserted into and coupled to the coupling part 173. Accordingly, the power conversion apparatus 100 is electrically connected to the uninterruptible power supply 10. Conversely, when the power conversion apparatus 100 is separated from the case 11, the connector 15 is separated from the coupling part 173.

As described above, in the power conversion apparatus 100 according to an embodiment of the present disclosure, since the coupling part 173 is detachably coupled to the connector 15, there is no need for a process to combine the power conversion apparatus 100 with a separate bus bar, thereby improving the convenience of assembling or disassembling the power conversion apparatus 100 for maintenance.

Although an embodiment of the present disclosure have been described, the spirit of the present disclosure is not limited to the embodiment presented in the subject specification; and those skilled in the art who understands the spirit of the present disclosure will be able to easily suggest other embodiments through addition, changes, elimination, and the like of elements without departing from the scope of the same spirit, and such other embodiments will also fall within the scope of the present disclosure.

1. A power conversion apparatus including:
a housing comprising an upper part, a lower part disposed in parallel with the upper part, a first side part connecting the upper part and the lower part, and a second side part disposed in parallel with the first side part;
a plurality of transistors disposed adjacent to the first side part inside the housing;
a heat sink disposed on one side of the plurality of transistors and providing a passage through which air introduced from the outside moves; and
a plurality of capacitors disposed in front of the heat sink,
wherein the plurality of capacitors are disposed to be spaced apart from each other so that air introduced from the outside of the housing moves to the heat sink.

2. The power conversion apparatus according to claim 1, wherein the plurality of transistors are disposed in parallel with the upper part, and
the plurality of transistors are disposed to be alternately spaced apart from each other by a first interval and a second interval greater than the first interval.

3. The power conversion apparatus according to claim 2, wherein the plurality of capacitors include:
a plurality of first capacitors arranged in a row parallel with the first interval; and
a plurality of second capacitors arranged in two rows parallel with the second interval.

4. The power conversion apparatus according to claim 3, wherein the plurality of second capacitors are disposed to be spaced apart from each other at a third interval smaller than the first interval, and
the plurality of first capacitors and the plurality of second capacitors is disposed to be spaced apart from each other at a fourth interval greater than the third interval.

5. The power conversion apparatus according to claim 4, wherein some capacitors disposed at the front among the plurality of second capacitors are disposed to be spaced apart from each other at a fifth interval greater than the fourth interval.

6. The power conversion apparatus according to claim 1, further including an air blocking unit having a plate shape and formed to have a plurality of passage holes through which the plurality of capacitors pass,
wherein the air blocking unit blocks air introduced into the plurality of capacitors from being moved to the plurality of transistors.

7. The power conversion apparatus according to claim 1, further including an air guide extending from the second side part and formed to be inclined,
wherein the air guide guides air introduced from the outside to be supplied to one side of the heat sink.

8. The power conversion apparatus according to claim 1, further including:
a substrate electrically connected to the transistor and the plurality of capacitors;
a bus bar having one end electrically connected to the substrate and the other end protruding to the rear of the housing; and
a coupling part coupled to the other end of the bus bar and detachably coupled to the connector of the uninterruptible power supply.
